(19) United States
(12) Patent Application Publication
(10) Pub. No.: US 2026/0074702 A1
(43) Pub. Date: Mar. 12, 2026

(54) SEMICONDUCTOR DEVICE

(71) Applicant: Renesas Electronics Corporation, Tokyo (JP)

(72) Inventors: Kentaro KIMOTO, Tokyo (JP); Masafumi WATANABE, Tokyo (JP); Satoshi ONISHI, Tokyo (JP); Hidenori ORINO, Tokyo (JP)

(21) Appl. No.: 19/261,062

(22) Filed: Jul. 7, 2025

(30) Foreign Application Priority Data
Sep. 10, 2024 (JP) 2024-156812

(51) Int. Cl. H03L 7/089; H03L 7/091

(52) U.S. Cl. CPC H03L 7/0898; H03L 7/091; H03L 2207/50

(57) ABSTRACT

Provided is a semiconductor device that suppresses an increase in an area and current of a PLL. An ADPL and an SPLL are included, and an SPD that compares an input signal with a feedback signal from a CCO, a charge pump circuit that outputs a current or a voltage based on a result of the SPD, a PFD that detects a phase difference which is a comparison result between the input signal and the feedback signal, and a phase difference digitizer that changes the current output by the charge pump circuit based on a detection result of the PFD are included.

### CROSS-REFERENCE TO RELATED APPLICATIONS

The disclosure of Japanese Patent Application No. 2024-156812 filed on Sep. 10, 2024 including the specification, drawings and abstract is incorporated herein by reference in its entirety.

### BACKGROUND

The present invention relates to a semiconductor device, for example, a semiconductor device including a phase-locked loop circuit. Phase-locked loops (PLLs) are commonly used as oscillator circuits mounted in semiconductor devices. A PLL is a circuit that controls the oscillation frequency of an output signal so that the phase of an input signal and the phase of an output signal are synchronized.

In recent system-on-chip (SoC) products, a plurality of PLLs are mounted for embedded microcontrollers, communication circuits, and the like. A plurality of PLLs may differ not only in the frequencies of the clock signals they output, but also in the characteristics required of the clock signals. For example, a spread-spectrum clock may be required for a microcontroller, whereas a low-jitter clock may be required for a communication circuit.

There are disclosed techniques listed below.

[Non-Patent Document 1] Ahmed Elkholy, Amr Elshazly, Saurabh Saxena, Guanghua Shu, Pavan Kumar Hanumolu, “A 20-to-1000 MHz±14 ps Peak-to-Peak Jitter Reconfigurable Multi-Output All-Digital Clock Generator Using Open-Loop Fractional Dividers in 65 nm CMOS”, 2014 IEEE International Solid-State Circuits Conference Digest of Technical Papers (ISSCC) 2014-02

Therefore, mounting a plurality of PLLs increases the area occupied by a PLL section. Accordingly, integrating the plurality of PLLs into a single unit has been proposed. For example, Non-Patent Document 1 describes a configuration consisting of an integer-N PLL followed by a plurality of fractional frequency dividers, in which the PLL generates a 5 GHz output from a 100 MHz reference clock. Each fractional frequency divider is independently controlled by a 7-bit integer and a 14-bit fractional frequency control words, and is described that the integer division ratio N is controlled from 4 to 127, and further, the fractional part α is controlled to set the division ratio to N+α.

### SUMMARY

However, in the circuit configuration described in Non-Patent Document 1, the area occupied by the fractional frequency divider becomes large. Furthermore, a high-speed clock signal is required to control the fractional frequency divider, resulting in an increase in current on the PLL side.

Embodiments described later have been made in view of such circumstances, and other problems and novel features will become apparent from the following description of the present specification and the accompanying drawings.

According to one embodiment, a semiconductor device includes a first phase-locked loop circuit including a first oscillator and a phase frequency control unit that performs phase control and frequency control on the first oscillator, and a second phase-locked loop circuit including a second oscillator whose frequency is controlled by a signal output from the phase frequency control unit, and a phase control unit that performs phase control on the second oscillator, in which the second phase-locked loop circuit is composed of a sampling PLL, and in which the phase control unit includes a first phase comparator that compares a phase of an input signal with a feedback signal from the second oscillator, a charge pump circuit that outputs a current based on a result of the first phase comparator, and a charge pump control circuit that changes a current output by the charge pump circuit based on a phase difference between the input signal and the feedback signal.

According to the above one embodiment, it is possible to suppress an increase in the area and current of the PLL.

### BRIEF DESCRIPTION OF THE DRAWINGS

FIG. 1 is a schematic configuration diagram of a semiconductor device according to a first embodiment.

FIG. 2A is an explanatory diagram illustrating a lock state of phase comparison in a typical sampling PLL.

FIG. 2B is an explanatory diagram illustrating a lock process of phase comparison in a typical sampling PLL.

FIG. 3 is a diagram illustrating a case where the phase difference between FD and FR is equal to or greater than a lock range in the typical sampling PLL.

FIG. 4 is a graph illustrating charge pump current characteristics and charge pump gain characteristics of a typical analog PLL and the sampling PLL.

FIG. 5 is a circuit example of the sampling PLL illustrated in FIG. 1.

FIG. 6 is an explanatory diagram of an operation of a phase difference digitizer.

FIG. 7 is a graph illustrating the charge pump current characteristics and charge pump gain characteristics of the sampling PLL according to the present embodiment.

FIG. 8 is a schematic configuration diagram of a semiconductor device according to a second embodiment.

FIG. 9 is a schematic configuration diagram of a semiconductor device according to a third embodiment.

### DETAILED DESCRIPTION

In the following embodiments, for the sake of convenience, the description may be divided into a plurality of sections or embodiments where appropriate. However, unless explicitly stated otherwise, such divisions are not mutually exclusive; rather, in that one may be a modification, a detail, or a supplementary explanation of the other, either in whole or in part. Further, in the following embodiments, when referring to the number of elements (including quantities, numerical values, amounts, ranges, etc.), unless explicitly stated otherwise or unless it is clearly limited to a specific number by principle, the number is not to be construed as limiting, and may be more or less than the stated number.

Furthermore, in the following embodiments, it goes without saying that the components (including element steps and the like) are not necessarily essential unless explicitly stated or clearly considered essential in principle. Similarly, in the following embodiments, references to the shapes, positional relationships, etc. of constituent elements are intended to include those that are substantially similar or approximate thereto, unless explicitly stated otherwise or unless it is clearly not so from by principle. The same applies to the above-mentioned numerical values and ranges.

The circuit elements constituting each functional block in the embodiments are not particularly limited, but may be formed on a semiconductor substrate such as monocrystalline silicon using known integrated circuit techniques, such as complementary metal-oxide-semiconductor (CMOS) technique. In the embodiments, a Metal Oxide Semiconductor Field Effect Transistor (MOSFET), which is an example of a Metal Insulator Semiconductor Field Effect Transistor (MISFET), is used (hereinafter referred to as a “MOS transistor”); however, non-oxide films are not excluded as gate insulating films. Also, in the embodiments, a p-channel MOSFET and an n-channel MOSFET are referred to as a pMOS transistor and an nMOS transistor, respectively.

Hereinafter, embodiments of the present invention will be described in detail with reference to the drawings. In all the drawings for explaining the embodiments, the same reference numerals are basically assigned to the same components, and repeated explanations thereof are omitted.

### First Embodiment

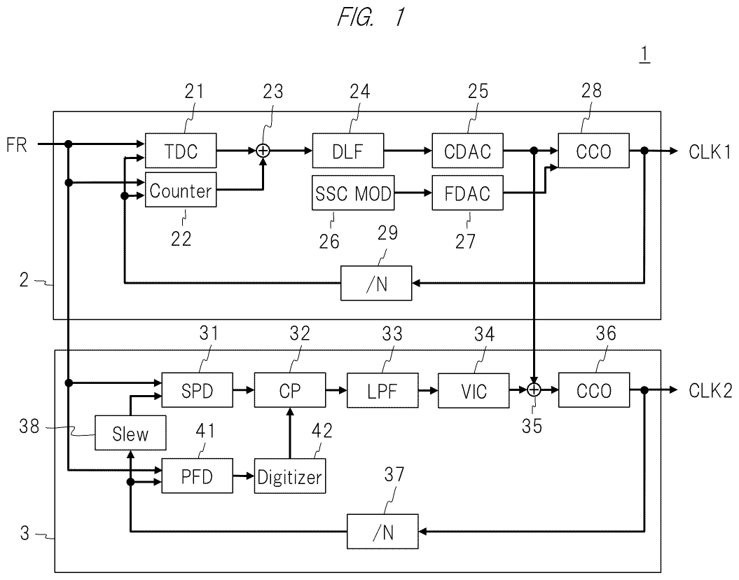

FIG. 1 illustrates a schematic diagram of a semiconductor device according to a present embodiment. FIG. 1 is a schematic configuration diagram of a PLL section of a semiconductor device 1 according to the present embodiment. The semiconductor device 1 includes an ADPLL 2 and an SPLL 3.

The ADPLL 2 is configured as an All-Digital Phase-Locked Loop (ADPLL). The ADPLL 2 includes a TDC 21, a counter 22, an arithmetic unit 23, a DLF 24, a CDAC 25, an SSC MOD 26, an FDAC 27, a CCO 28, and a frequency divider (/N) 29.

The TDC 21 detects a decimal phase difference between an input signal, which is a reference clock signal (hereinafter referred to as FR), and a feedback clock signal (feedback signal) output from the frequency divider 29, and outputs a signal representing the detected decimal phase difference to the arithmetic unit 23. Hereinafter, the feedback clock signal will be referred to as FD, and when distinction is necessary, it will be identified as “FD from the frequency divider 29” or the like. The counter 22 detects an integer phase difference between the FR and the FD from the frequency divider 29, and outputs a signal representing the detected integer phase difference to the arithmetic unit 23. The arithmetic unit 23 calculates and outputs a phase error between the FR and the FD from a frequency divider 37 based on a signal representing a phase difference supplied from the TDC 21 and the counter 22.

The DLF 24 is configured as a digital loop filter. The DLF 24 smooths the digital signal output from the arithmetic unit 23 and outputs the signal as a control code to the CDAC 25. The CDAC 25 is configured as a current-output-type DA converter. The CDAC 25 outputs a control current corresponding to the value indicated by the control code to the CCO 28. The SSC MOD 26 is configured with the modulation depth and the like of the spread spectrum clock (SSC CLK), and outputs a modulation signal based on the modulation depth and the like. The FDAC 27 converts the modulation signal into a control current and outputs the current to the CCO 28.

The CCO 28 is configured as a current controlled oscillator. The CCO 28 outputs an output clock signal (CLK 1) having a frequency and a phase corresponding to the control current. The output clock signal output from the CCO 28 becomes the spread-spectrum clock (SSCG CLK). The frequency divider 29 divides the output clock signal output from the CCO 28 by 1/N.

That is, the ADPLL 2 functions as a first phase-locked loop circuit. Further, the TDC 21, the counter 22, the arithmetic unit 23, the DLF 24, the CDAC 25, and the frequency divider (/N) 29 function as a phase frequency control unit, and the CCO 28 functions as a first oscillator.

The SPLL 3 is configured based on a well-known sampling PLL. The SPLL 3 includes an SPD 31, a charge pump circuit (CP) 32, an LPF 33, a VIC 34, an adder 35, a CCO 36, the frequency divider 37, a slew rate controller (Slew) 38, a PFD 41, and a phase difference digitizer (Digitizer) 42.

The SPD 31 is configured as a phase comparator. The SPD 31 detects a phase difference between the FR and the FD, whose edges have been slowed by the slew rate controller 38 (to be described later), and outputs a current according to the phase difference. That is, the SPD 31 functions as a first phase comparator.

The charge pump circuit 32 includes a circuit for the integral path and a circuit for the proportional path. The circuit for the integral path outputs a predetermined current based on the current output from the SPD 31 and a pulse signal output from the phase difference digitizer 42, which will be described later. The circuit for the proportional path outputs a current based on the current output by the SPD 31. The LPF 33 is configured as a loop filter (filter circuit). The LPF 33 smooths the output of the charge pump circuit 32 and outputs it.

The VIC 34 outputs a current to the CCO 36 in accordance with the output of the LPF 33. The CCO 36 is configured as a current controlled oscillator. The CCO 36 outputs an output clock signal (CLK 2) having a frequency and a phase corresponding to the combined current (i.e., the output of the adder 35), which is the sum of the current output from the VIC 34 and the control current output from the CDAC 25. That is, the SPLL 3 can control the frequency based on the current (signal) output from the ADPLL 2. The frequency divider 37 divides the output clock signal output from the CCO 36 by 1/N.

The slew rate controller 38 slows the edge (rising and falling) of the FD, which is the output of the frequency divider 37, and outputs it. The PFD 41 is configured as a phase comparator. The PFD 41 detects a phase difference between the FR and the FD from the frequency divider 37, and outputs a DN signal or an UP signal indicating whether the phase difference is leading or lagging. The pulse width of the DN signal or the UP signal indicates the magnitude of the phase difference.

The phase difference digitizer 42 outputs a pulse signal whose pulse width corresponds to the pulse width of the DN signal or the UP signal. The phase difference digitizer 42 detects how many oscillation cycles of the CCO 36 correspond to a phase difference between the FR and the FD from the frequency divider 37, and outputs a pulse signal corresponding to the detected number of cycles. The phase difference digitizer 42 will be described in detail later.

That is, the SPLL 3 functions as a second phase-locked loop circuit. Further, the SPD 31, the charge pump circuit 32, the LPF 33, the VIC 34, the adder 35, the frequency divider 37, the slew rate controller (Slew) 38, the PFD 41, and the phase difference digitizer 42 function as a phase control unit, and the CCO 36 functions as a second oscillator. Also, the PFD 41 and the phase difference digitizer 42 function as a charge pump control circuit.

### [Problem of Present Embodiments]

Next, the problem of the present embodiment will be described. In the present embodiment, as illustrated in FIG. 1, a configuration is adopted in which the sampling PLL, the SPLL 3, is added to the ADPLL 2 that functions as a spread-spectrum clock generator (SSCG). With this configuration, a frequency control function of the SPLL 3 can be shared with the ADPLL 2, making it possible to reduce the area required for the frequency control filter and the like in the SPLL 3. Furthermore, typically, a sampling PLL holds phase difference information and continuously supplies a small current, making it possible to eliminate the need for a filter and thereby reduce the area therefor. In addition, continuous operation allows for an increase in loop bandwidth. Accordingly, the SPLL 3 enables a high loop bandwidth with a small current, thereby making it possible to output a low-jitter clock signal with a small area.

Typically, a sampling PLL slows the edge of the feedback clock signal (FD), samples the signal using the reference clock signal (FR), and holds the resulting phase difference as a voltage value using a capacitor. Then, the voltage is converted into a current and injected into the oscillator (CCO). By sampling the slowed edge of the feedback clock signal (FD), it becomes possible to detect minute phase differences, enabling the generation of a low-jitter clock signal.

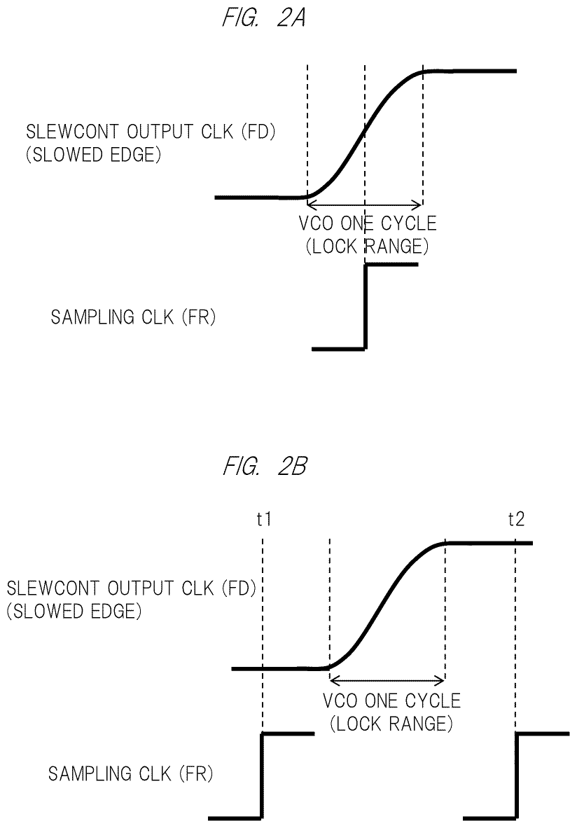

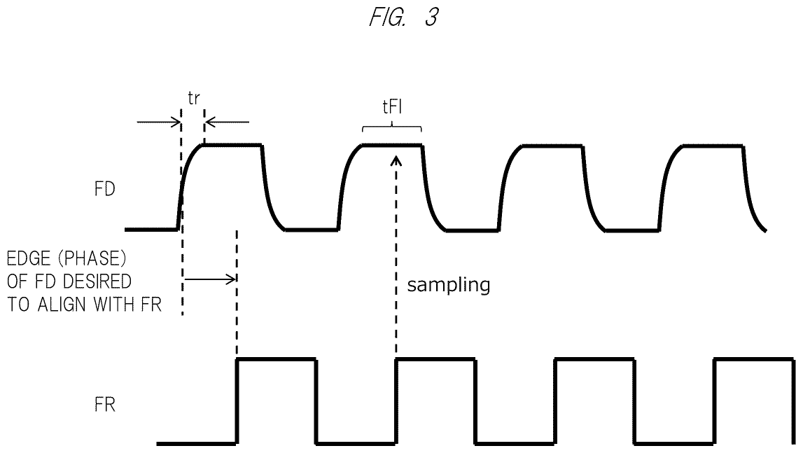

However, typical sampling PLLs have the following problem. In the locked state of a sampling PLL, the edges of the FR and the FD align, so the linear portion of the FD edge is sampled, and the charge pump current changes linearly (see FIG. 2A). On the other hand, during the locking process, the phase difference between the FR and the FD is large, causing sampling to occur at points other than the edge (at t1 and t2 in FIG. 2B). In that case, it becomes impossible to determine how much the phase difference between the FR and the FD has deviated. In a sampling PLL, the phase comparison range (the range where gain exists) is narrow, limited to only one oscillation cycle of the oscillator in the sampling PLL. This is the problem of a sampling PLL.

Next, the effect of low gain will be explained. FIG. 3 illustrates waveforms of the FD and the FR, illustrating the case where their phase difference exceeds the lock range (tr). As illustrated in FIG. 3, although it is desirable to align the edge of the FD with the FR, sampling a flat section tFl of the FD using the FR results in the same voltage (and thus the same current), making it impossible to determine how far apart the phases are. Since the charge pump current when sampling the flat section tFl of the FD is very small, the edge of the FD does not approach the FR. In other words, the force to align the frequency and phase is weak, and if the gain (current) is small, the phases cannot be aligned (lock cannot be achieved).

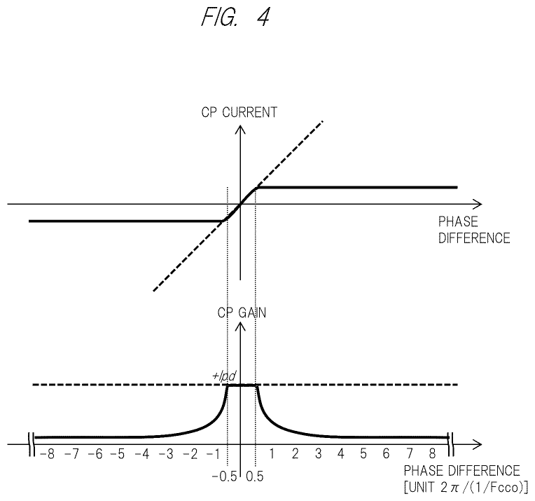

Next, the charge pump current characteristics of the sampling PLL will be described. FIG. 4 is a graph illustrating charge pump current characteristics (upper part) and charge pump gain characteristics (lower part) of a typical analog PLL and the sampling PLL. In FIG. 4, the solid lines indicate the sampling PLL, while the dashed lines indicate the analog PLL.

Here, the analog PLL will be briefly described. As is well known, an analog PLL performs phase comparison between the FR and the FD using a phase-frequency comparator, detects the phase difference, and outputs a pulse. Then, in an INT path (integral path), a current corresponding to the pulse width is output from the charge pump and accumulated according to the capacitance. The voltage, which reflects the accumulated capacitance, is then converted into a current to determine the oscillation frequency (frequency control). On the other hand, in a PROP path (proportional path), a current corresponding to the pulse width is output from the charge pump, then smoothed by a loop filter to suppress jitter, and input into the oscillator to control the phase (phase control).

In a typical analog PLL, as illustrated by the dashed line in the upper part of FIG. 4, the charge pump current varies linearly with the phase difference. In other words, an analog PLL outputs a large charge pump current when the phase difference is large, and a small current when the phase difference is small, thereby enabling it to output a current according to the phase difference. Also, as illustrated by the dashed line in the lower part of FIG. 4, the gain of the analog PLL remains constant. In other words, even when there is a phase difference, the charge pump in an analog PLL maintains a constant gain.

On the other hand, as illustrated by the solid line in the upper part of FIG. 4, the sampling PLL shows linear variation in current only within the region where the edge of the FD is sampled (i.e., within a phase difference range of ±0.5); outside this range, the current remains constant. In other words, in a sampling PLL, a constant charge pump current flows when the phase difference is large, whereas within a narrow range of phase difference, the charge pump current varies according to the phase difference. Also, as illustrated by the solid line in the lower part of FIG. 4, the sampling PLL has a region where the charge pump gain decreases. In other words, the gain is normal only within a narrow range of phase difference near the edge, and the gain decreases as the phase difference increases. In other words, the sampling PLL has a narrow lock range (phase comparison range).

In a typical sampling PLL, frequency control is performed using a Frequency Locked Loop (FLL) to address the above problem. However, in the present embodiment, the oscillator on the FLL side is configured independently and also serves as an SSCG output. Therefore, the PLL in the present embodiment includes two oscillators, the CCO 28 and the CCO 36. Due to mismatches and the like, a frequency difference may arise between them, however, because the lock range of the sampling PLL is narrow, it may not be possible to achieve lock using only the conventional loop control of the sampling PLL.

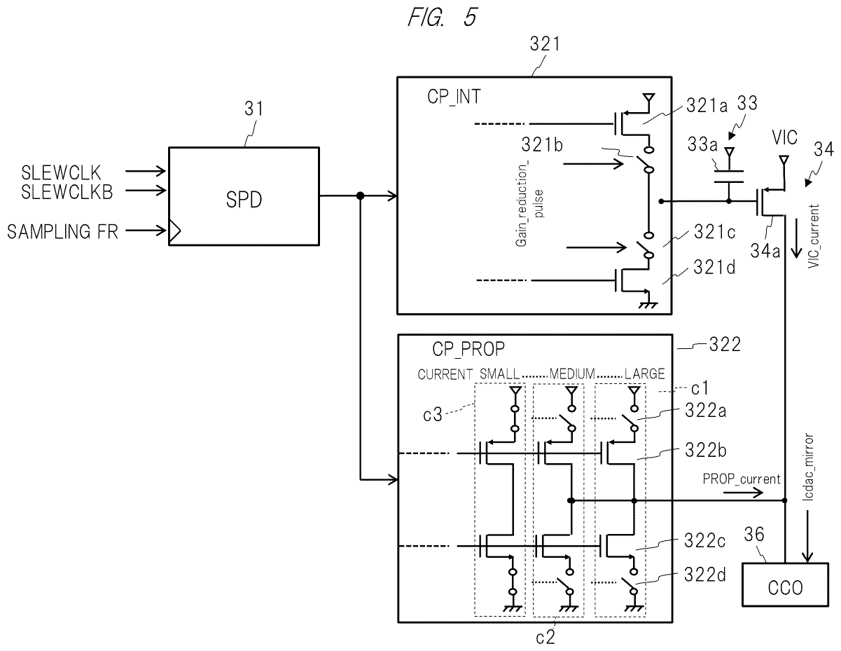

To address the above problem, the SPLL 3 of the present embodiment includes the phase difference digitizer 42, which coarsely detects a phase difference larger than those near the lock point and outputs it as a digital value. By using the phase difference digitizer 42, the output current (weighting) of the charge pump circuit 32 in the SPLL 3 is varied so that the output of the charge pump circuit 32 becomes proportional to the phase difference. As a result, the output of the charge pump circuit 32 is brought closer to the ideal characteristics illustrated by the dashed line in the upper part of FIG. 4, thereby solving the problem of the narrow lock range.

[Circuit Example of Sampling PLL] FIG. 5 illustrates a circuit example of the SPLL 3 illustrated in FIG. 1. FIG. 5 is a circuit diagram corresponding to a section including the SPD 31, the charge pump circuit 32, the LPF 33, the VIC 34, and the CCO 36 illustrated in FIG. 1. In the circuit of FIG. 5, SLEWCLK and SLEWCLKB are input to the SPD 31 as the FD. This is because the circuit in FIG. 5 is configured as a differential circuit. In other words, the output signals of the slew rate controller 38, SLEWCLK and SLEWCLKB, are in opposite phase. Note that a differential circuit such as that illustrated in FIG. 5 is not necessarily required. Then, as described above, SAMPLING FR (FR) is input to the SPD 31. The SPD 31 samples SLEWCLK and SLEWCLKB using the FR, holds the voltage values in internal capacitive elements, and outputs a current according to the phase difference.

As illustrated in FIG. 5, the charge pump circuit 32 is composed of a CP_INT 321 and a CP_PROP 322. The CP_INT 321 is a charge pump circuit in the integral path. The CP_INT 321 includes a pMOS transistor 321a, switches 321b and 321c, and an nMOS transistor 321d.

The pMOS transistor 321a, the switches 321b and 321c, and the nMOS transistor 321d are connected in series. That is, a source of the pMOS transistor 321a is connected to the power supply, a drain of the pMOS transistor 321a is connected to one terminal of the switch 321b, and another terminal of the switch 321b is connected to one terminal of the switch 321c. The other terminal of switch 321c is connected to a drain of the nMOS transistor 321d, and a source of the nMOS transistor 321d is grounded to the reference potential. Signals based on the output from the SPD 31 are input to gates of the pMOS transistor 321a and the nMOS transistor 321d. In the circuit illustrated in FIG. 5, since the SPD 31 is a differential circuit, signal lines based on SLEWCLK and SLEWCLKB are respectively connected to the gates of the pMOS transistor 321a and the nMOS transistor 321d.

The switches 321b and 321c have their on-time controlled by the pulse signal (Gain_reduction_pulse) output from the phase difference digitizer 42. The control of the switches 321b and 321c by the Gain_reduction_pulse will be described later.

The connection point between another terminal of the switch 321b and the one terminal of the switch 321c serves as the output of the CP_INT 321.

The CP_PROP 322 is a charge pump circuit in the proportional path. The CP_PROP 322 includes circuits c1, c2, and c3. The circuit c1 includes a switch 322a, a pMOS transistor 322b, an nMOS transistor 322c, and a switch 322d.

The switch 322a, the pMOS transistor 322b, the nMOS transistor 322c, and the switch 322d are connected in series. That is, one terminal of the switch 322a is connected to the power supply, another terminal of the switch 322a is connected to the source of the pMOS transistor 322b, and the drain of the pMOS transistor 322b is connected to the drain of the nMOS transistor 322c. Also, the source of the nMOS transistor 322c is connected to one terminal of the switch 322d, and another terminal of the switch 322d is grounded to the reference potential.

Signals based on the output from the SPD 31 are input to the gates of the pMOS transistor 322b and the nMOS transistor 322c. In the circuit illustrated in FIG. 5, since the SPD 31 is a differential circuit, signal lines based on SLEWCLK and SLEWCLKB are respectively connected to the gates of the pMOS transistor 322b and the nMOS transistor 322c. The same applies to the pMOS and the nMOS transistors included in the circuits c2 and c3.

The connection point between the drain of the pMOS transistor 322b and the drain of the nMOS transistor 322c serves as the output of the CP_PROP 322. The same applies to the circuits c2 and c3. The output of CP_PROP 322 is a current (PROP_current).

The circuits c2 and c3 have the same configuration as the circuit c1. The CP_PROP 322 turns on or off the switches of each circuit c1, c2, and c3 according to the phase difference. <For example, when the phase difference is large, all switches of the circuits c1, c2, and c3 (each corresponding to the large, medium, and small currents in FIG. 5) are turned on to allow a larger current to flow, thereby inducing a greater phase shift. When the phase difference is moderate, the switches of the circuits c2 and c3 (corresponding to the medium and small currents) are turned on to induce a moderate phase change. When the phase difference is near zero, only the switches of the circuit c3 (corresponding to the small current in FIG. 5) are turned on to reduce the current and thereby inducing a minute phase change.

Note that, in FIG. 5, only the circuits c1, c2, and c3 are illustrated due to space limitations. In practice, however, the phase difference is controlled in eight steps using the result of counting the phase difference with the output clock of the CCO 36 in the phase difference digitizer 42, which will be described later. That is, a plurality of similar circuits are provided between the circuit c1 (large) and the circuit c2 (medium) and between the circuit c2 (middle) and the circuit c3 (small) in FIG. 5, and the number of circuits with switches turned on is varied from 1 to 8 according to the phase difference.

When it is “near zero in phase difference”, only the circuit c3 is turned on, and the result of the SPD 31 is used to output a current (PROP_current) corresponding to the minute phase difference.

Although the switches included in the CP_INT 321 and the CP_PROP 322 are illustrated as switches in FIG. 5, it goes without saying that they may be implemented using switching elements such as transistors, specifically.

The LPF 33 includes a capacitive element (capacitor) 33a. One terminal of the capacitive element 33a is connected to the power supply, and another terminal is connected to the output line of the CP_INT 321. The VIC 34 includes a pMOS transistor 34a. The pMOS transistor 34 a has a source connected to the power supply and a drain connected to the CCO 36. Moreover, a gate of the pMOS transistor 34a is connected to the output line of the CP_INT 321. In the pMOS transistor 34a, a drain current (VIC_current) flows toward the CCO 36 in accordance with the voltage smoothed by the LPF 33 from the output of the CP_INT 321.

Also, the output of the CP_PROP 322 is also connected between a drain of the pMOS transistor 34a and the CCO 36. Accordingly, the combined current of the VIC_current and the PROP_current flows into the CCO 36.

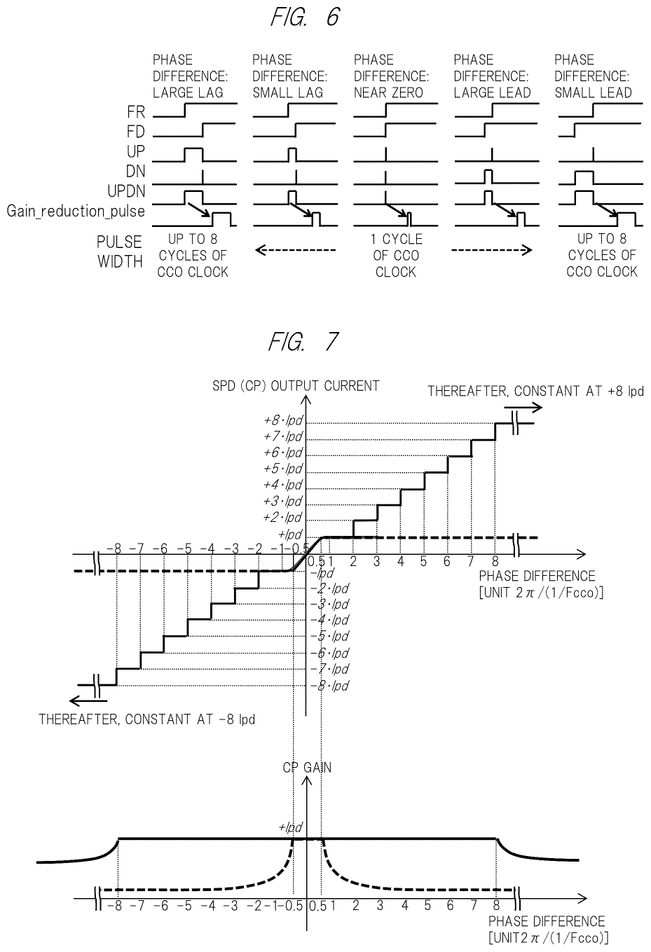

Then, in the CCO 36, the oscillation frequency and phase are determined based on the control current (Icdac_mirror) output from the CDAC 25, together with the combined current of the VIC_current and the PROP_current.

[Operation of Phase Difference Digitizer] Next, the Operation of the phase difference digitizer 42 will be described. FIG. 6 is an explanatory diagram of the generation of the above-mentioned Gain_reduction_pulse. FIG. 6 is a diagram illustrating the pulse width of the Gain_reduction_pulse in each case, from left to right: large lag in phase difference, small lag in phase difference, near-zero phase difference, small lead in phase difference, and large lead in phase difference.

When it is “large lag in phase difference”, that is, when the FD from the frequency divider 37 lags behind the FR in phase and the magnitude of the lagging is relatively large, the PFD 41 outputs an UP signal to advance the phase of the FD as a result of phase comparison of the FD and the FR. The pulse width of the UP signal corresponds to the width of the phase difference. The phase difference digitizer 42 calculates a UPDN signal, which is an OR signal of the UP signal and the DN signal, and generates and outputs a Gain_reduction_pulse having a pulse width equal to the number of oscillation cycles (clock cycles) of the CCO 36 according to the pulse width of the UPDN signal. In the example of FIG. 6, a Gain_reduction_pulse having a maximum of eight clock cycles of the CCO 36 is generated.

The pulse width of the Gain_reduction_pulse can be calculated by, for example, counting the pulse width of the UPDN signal using the output clock of the CCO 36. Therefore, the pulse width of the Gain_reduction_pulse is an integer multiple of the clock cycle (oscillation cycle) of the CCO 36.

Next, when it is “small lag in phase difference”, that is, when the FD from the frequency divider 37 lags behind the FR in phase and the magnitude of the lagging is relatively small, the basic operation is the same as when it is “large lag in phase difference”. When it is “small lag in phase difference”, the pulse width of the UP signal becomes smaller according to the phase difference, and therefore the pulse width of the UPDN signal also becomes smaller. Therefore, the pulse width of the Gain_reduction_pulse also falls within the range of 2 to 7 clock cycles of the CCO 36.

Next, it is “near zero in phase difference”, that is, when the FD from the frequency divider 37 and the FR are approximately the same, the pulse widths of both the UP signal and the DN signal become remarkably small. Therefore, the pulse width of the UPDN signal is also remarkably small. In this case, the pulse width of the Gain_reduction_pulse is set to one clock cycle of the CCO 36. That is, the pulse width of the Gain_reduction_pulse becomes one clock cycle of the CCO 36 when the pulse width of the UPDN signal counted by the output clock of the CCO 36 becomes 1 or less.

Next, when it is “small lead in phase difference”, that is, when the FD from the frequency divider 37 leads the FR in phase and the magnitude of the leading is relatively small, the basic operation is the same as when it is “lag in phase difference”. When it is “small lead in phase difference”, the PFD 41 outputs the DN signal to delay the phase of FD based on the phase comparison between the FD and the FR. The pulse width of the DN signal corresponds to the width of the phase difference. The phase difference digitizer 42 generates and outputs a Gain_reduction_pulse having a pulse width of the clock cycle(s) of the CCO 36 corresponding to the pulse width of the UPDN signal. When it is “small lead in phase difference”, the pulse width of the Gain_reduction_pulse falls within the range of 2 to 7 clock cycles of the CCO 36.

Next, when it is “large lead in phase difference”, that is, when the FD from the frequency divider 37 leads the FR in phase and the magnitude of the leading is relatively large, the basic operation is the same as when it is “small lead in phase difference”. When it is “large lead in phase difference”, the pulse width of the DN signal increases according to the phase difference, and therefore the pulse width of the UPDN signal also increases. Therefore, the pulse width of the Gain_reduction_pulse becomes eight clock cycles of the CCO 36.

That is, the PFD 41 functions as a second phase comparator that compares the phase of the input signal and the feedback signal, and the phase difference digitizer 42 functions as a pulse generation circuit that generates a pulse signal indicating the magnitude of the phase difference between the input signal and the feedback signal based on the comparison result by the second phase comparator. And, the current of the charge pump circuit 32 is changed based on the pulse signal.

In the present embodiment, the pulse width of the Gain_reduction_pulse is set to a maximum of eight clock cycles of the CCO 36, but is not limited thereto. The maximum value of the pulse width (maximum cycles) of the Gain_reduction_pulse may be changed as appropriate according to, for example, the characteristics of the CCO 36 and the specifications of the SPLL 3.

The Gain_reduction_pulse generated as described above is used to control the switches 321b and 321c of the CP_INT 321 as illustrated in FIG. 5. When the phase difference is large, the pulse width of the Gain_reduction_pulse becomes large. Therefore, the on-time of the switches 321b and 321c becomes longer, and the VIC_current becomes larger, making the change in frequency large. Also, when the phase difference is medium, the pulse width of the Gain_reduction_pulse is shorter than when the phase difference is large. Therefore, the on-time of the switches 321b and 321c is shorter than when the phase difference is large, and the VIC_current is smaller than when the phase difference is large, making the change in frequency medium. When the phase difference is near zero, the result of the SPD 31 is used, so that the pulse width of the Gain_reduction_pulse becomes the minimum, that is, one clock cycle of the CCO 36.

FIG. 7 is a graph illustrating charge pump current characteristics (upper part) and charge pump gain characteristics (lower part) of the SPLL 3 of the present embodiment. In FIG. 7, the solid line indicates the SPLL 3 of the present embodiment having the phase difference digitizer 42, and the dashed line indicates the conventional sampling PLL illustrated by the solid line in FIG. 4.

As described above, in the SPLL 3 of the present embodiment, in a region where the phase difference is large, a Gain_reduction_pulse having a wide pulse width is output, and a large charge pump current flows. In a region where the phase difference is small, a Gain_reduction_pulse with a narrow pulse width is output, and the charge pump current is reduced. And the pulse width increases or decreases in units of the clock cycle of the CCO 36. Therefore, as illustrated in FIG. 7, the SPLL 3 of the present embodiment has stepwise current characteristics, and is able to output a current proportional to the phase difference. That is, by changing the weighting of the output of the charge pump circuit 32, the charge pump current characteristics can be made to discretely approach that of the analog PLL illustrated in FIG. 4. That is, the output current of the charge pump circuit 32 is changed based on the comparison result of between the input signal and the feedback signal by the Gain_reduction_pulse.

To further describe the upper part of FIG. 7, when the phase difference is between −0.5 and +0.5, the current changes linearly by adopting the result of sampling the slowed FD, which is the output of the slew rate controller 38, at the FR. On the other hand, in the other regions, by adopting the results of the phase difference digitizer 42, fine phase control is applied near the lock point, while coarse phase control is applied to the rest of the regions, resulting in a stepwise change in current. Therefore, the phase comparison range can be expanded.

As also illustrated in the lower part of FIG. 7, by adding the phase difference digitizer 42, the gain becomes constant (solid line), and the phase can be pulled in even when the phase difference is large.

According to the above configuration, by providing the SPLL3 with both the PFD 41 and the phase-difference digitizer 42, the phase comparison range (lock range) can be expanded without the need to include additional frequency control circuits such as an FLL in the sampling PLL.

Furthermore, by providing the PFD 41 and the phase difference digitizer 42, it becomes possible to generate a pulse signal according to the phase difference detected by the PFD 41. The pulse signal, by being generated in units of the clock cycle of the CCO 36, can cause the charge pump current characteristics to exhibit stepwise current characteristics, thereby enabling the output of a current proportional to the phase difference. Consequently, the charge pump current characteristics can discretely approximate that of an analog PLL.

Furthermore, by configuring the phase difference digitizer 42 as a circuit that generates pulse signals in units of the clock cycle of the CCO 36, it can be configured with a logic circuit and can be a smaller circuit than a frequency control circuit such as an FLL.

Furthermore, by adding the SPLL 3 to the ADPLL 2, the frequency control function of the SPLL 3 can be shared with the ADPLL 2, and the area of the frequency control filter and the like in the SPLL3 can be reduced. Furthermore, the SPLL 3 holds phase difference information and continuously supplies a small current, making it possible to eliminate the need for a filter and thereby reduce the area therefor. In addition, continuous operation allows for an increase in loop bandwidth. Accordingly, the SPLL 3 enables a high loop bandwidth with a small current, thereby making it possible for the SPLL 3 to output a low-jitter clock signal with a small area.

### Second Embodiment

Next, a second embodiment will be described. In the following, descriptions of portions that overlap with the above embodiment will be omitted in principle.

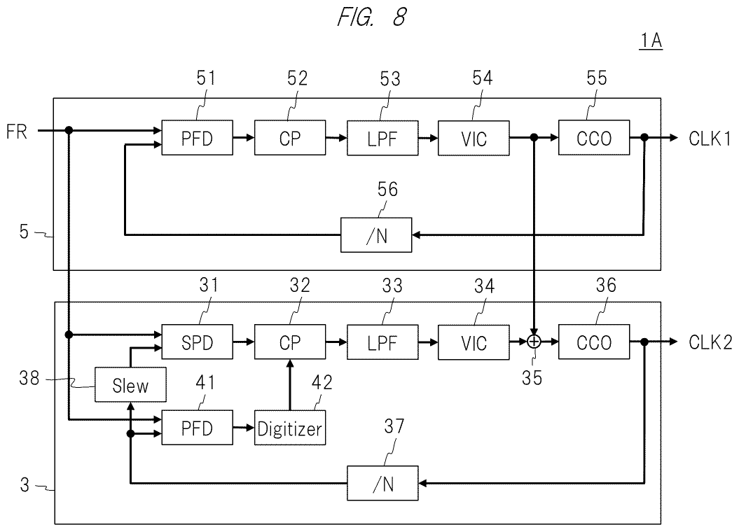

The present embodiment differs in that the ADPLL 2 is replaced with an analog PLL 5 as the first phase-locked loop circuit. FIG. 8 is a schematic configuration diagram of a PLL section of a semiconductor device 1A according to the present embodiment.

The analog PLL 5 includes a PFD 51, a charge pump circuit 52, a loop filter 53, a VIC 54, a CCO 55, and a frequency divider (/N) 56.

The PFD 51 is configured as a phase comparator. The PFD 51 detects the phase difference between the FR and the output (FD) of the frequency divider 56, and outputs a pulse signal according to the phase difference. The charge pump circuit 52 has an integral path and a proportional path, and the integral path outputs a current in response to the pulse signal and accumulates it in a capacitor. The proportional path outputs a current according to the pulse width. The LPF 53 is configured as a loop filter. The LPF 53 smoothes the current supplied from the proportional path of the charge pump circuit 52 and outputs the smoothed current.

The VIC54 is configured as a voltage-current conversion circuit. The VIC 54 converts the voltage, which corresponds to the charge accumulated in the integral path, into a current and outputs it to the CCO 55. The CCO 55 is configured as a current controlled oscillator. The CCO 55 determines the frequency and the phase based on the current output by the VIC 54 and the current from the proportional path, and outputs an output clock signal (CLK 1). The frequency divider 55 divides the output clock signal output from the CCO 56 by 1/N.

In the present embodiment, the PFD 51, the charge pump circuit 52, the loop filter 53, the VIC 54, and the frequency divider 56 function as a phase frequency control unit, and the CCO 55 functions as a first oscillator.

The output current of the VIC 54 is also output to the adder 35 of the SPLL 3. Therefore, the SPLL 3 can share the frequency control function of the SPLL 3 with the analog PLL 5, similar to the configuration of FIG. 1. Therefore, according to the configuration of FIG. 8, clock signals of different frequencies can be output, and at least CLK 2 can be a low-jitter clock signal.

### Third Embodiment

Next, a third embodiment will be described. In the following, descriptions of portions that overlap with the above embodiments will be omitted in principle.

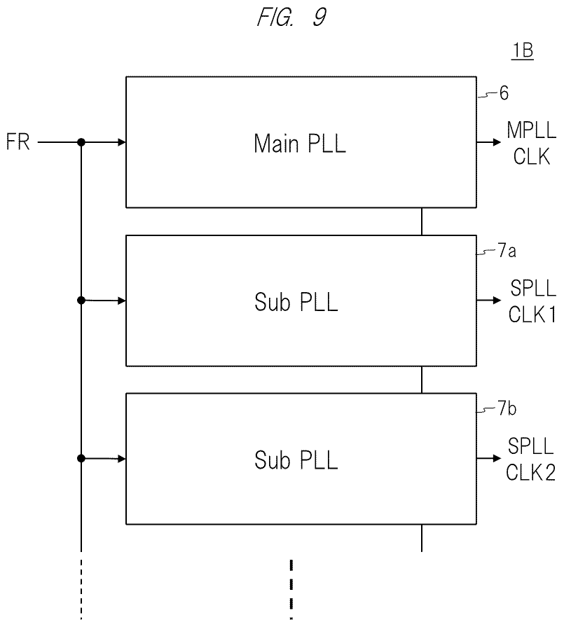

The present embodiment includes a plurality of second phase-locked loop circuits. FIG. 9 is a schematic configuration diagram of a PLL section of a semiconductor device 1B according to the present embodiment.

The semiconductor device 1B illustrated in FIG. 9 includes a Main PLL 6 and Sub PLLs 7a and 7b. The Main PLL 6 may be configured using the ADPLL 2 or analog PLL 5 illustrated in the first and second embodiments. The SubPLLs 7a and 7b are configured from the SPLL 3 illustrated in the first embodiment.

The output currents of the CDAC 25 and the VIC 54 of the MainPLL 6 are supplied to the adders 35 (CCO 36) of the SubPLLs 7a and 7b, respectively.

In the present embodiment, for example, if the MainPLL 6 is configured as the ADPLL 2 (SSCG), a spread-spectrum clock can be output as an output clock signal MPLLCLK. Furthermore, an output clock signal SPLLCLK 1 of the SubPLL 7a and an output clock signal SPLLCLK 2 of the SubPLL 7b may have different frequencies.

Also, as illustrated in FIG. 9, the number of SubPLLs may be two or more. By using the SPLL 3 described in the first embodiment, even if the number of SubPLLs increases, an increase in area can be suppressed.

In the foregoing, the invention made by the inventors of the present application has been concretely described on the basis of the embodiments. However, it is needless to say that the present invention is not limited to the foregoing embodiments, and various modifications and alterations can be made within the scope of the present invention.

What is claimed is:

1. A semiconductor device comprising:
a first phase-locked loop circuit including a first oscillator and a phase frequency control unit that performs phase control and frequency control on the first oscillator; and
a second phase-locked loop circuit including a second oscillator whose frequency is controlled by a signal output from the phase frequency control unit, and a phase control unit that performs phase control on the second oscillator,
wherein the second phase-locked loop circuit is composed of a sampling PLL, and
wherein the phase control unit includes
a first phase comparator that compares a phase of an input signal with a feedback signal from the second oscillator,
a charge pump circuit that outputs a current based on a result of the first phase comparator, and
a charge pump control circuit that changes a current output by the charge pump circuit based on a phase difference between the input signal and the feedback signal.

2. The semiconductor device according claim 1,
wherein the charge pump control circuit includes
a second phase comparator that compares a phase of the input signal with the feedback signal, and
a pulse generation circuit that generates a pulse signal indicating magnitude of the phase difference between the input signal and the feedback signal based on a comparison result by the second phase comparator, and
wherein, the charge pump circuit changes the current based on the pulse signal.

3. The semiconductor device according claim 2,
wherein a pulse width of the pulse signal is an integer multiple of an oscillation cycle of the second oscillator.

4. The semiconductor device according claim 1,
wherein the second phase-locked loop circuit is provided in plurality.

5. The semiconductor device according claim 1,
wherein the first phase-locked loop circuit is configured as a spread-spectrum clock generation circuit.
